(19) United States
(12) Patent Application Publication
(10) Pub. No.: US 2025/0328126 A1
(43) Pub. Date: Oct. 23, 2025

(54) INFORMATION PROCESSING APPARATUS, INFORMATION PROCESSING METHOD, NON-TRANSITORY COMPUTER-READABLE STORAGE MEDIUM, PATTERN FORMING APPARATUS, AND ARTICLE MANUFACTURING METHOD

(71) Applicant: CANON KABUSHIKI KAISHA, Tokyo (JP)

(72) Inventor: NAOKI MIYATA, Tochigi (JP)

(21) Appl. No.: 19/178,149

(22) Filed: Apr. 14, 2025

(30) Foreign Application Priority Data
Apr. 17, 2024 (JP) 2024-066824

(51) Int. Cl. G05B 19/418; G03F 7/00

(52) U.S. Cl. CPC G05B 19/4184; G03F 7/706837; G05B 2219/45031

(57) ABSTRACT

An information processing apparatus includes an obtaining unit configured to obtain a target value of a performance index of pattern formation, an estimation unit configured to estimate, for each of a plurality of regression models, an evaluation value of the performance index in a case where pattern formation is performed by correcting an array of a plurality of shot regions on a substrate, which is estimated by determining a plurality of sample shot regions from the plurality of shot regions based on the target value obtained by the obtaining unit and applying a regression model to the plurality of determined sample shot regions, and a controller configured to display the estimated evaluation value for each of the plurality of regression models on a display unit in a comparable form.

### BACKGROUND OF THE INVENTION

### Field of the Invention

The present invention relates to an information processing apparatus, an information processing method, a non-transitory computer-readable storage medium, a pattern forming apparatus, and an article manufacturing method.

### Description of the Related Art

An example of a pattern forming apparatus that forms a pattern on a substrate is a lithography apparatus. The lithography apparatus (for example, an exposure apparatus) can overlay the pattern of an original on a plurality of layers on a substrate and transfer it. To overlay the layers accurately, it is necessary to align each shot region of the substrate with the original. For example, an alignment mark arranged in each shot region on the substrate can be detected, and then the alignment can be performed based on position information of the alignment mark obtained by the detection and position information of the pattern of the original.

To implement accurate alignment, it is ideal to detect the alignment marks in all the shot regions on the substrate. However, this is not realistic from the viewpoint of productivity. Therefore, in general, a global alignment method is adopted to align all shot regions on a substrate and an original (see Japanese Patent Laid-Open Nos. 61-44429 and 62-84516).

In the global alignment method, it is assumed that the relative position of each of all shot regions on a substrate can be expressed by a function of the position coordinates of the shot region. Under this assumption, alignment marks only in some shot regions (sample shot regions) among the plurality of shot regions on the substrate are actually measured. Next, the parameters of the function model are estimated, using regression analysis-like statistic operation processing, from the assumed function model and the position measurement result. Using the estimated parameters and the function model, the position coordinates of each shot region on a stage coordinate system are calculated, thereby performing alignment. In the global alignment method, a polynomial model using stage coordinates as variables is used in general. Scaling that is a first-order polynomial of stage coordinates, rotation, uniform offset, and the like are mainly used (see Japanese Patent Laid-Open No. 6-349705).

There is also proposed a method using a regression model that considers, as a parameter, even a high-order component of the array of shot regions on the substrate (see Japanese Patent No. 3230271). Furthermore, there is proposed a method of measuring a plurality of sample points in advance, selecting a coefficient by a regression model having a regularization term and the data, and calculating position information of a shot region using the selected coefficient.

To perform alignment correction at high accuracy and high throughput, it is necessary to determine a regression model and a sample shot array suitable for a product by repeating a test while changing the sample shot array on the substrate with respect to a plurality of regression models. There exists a conventional method of automatically determining a condition (optimum condition) suitable for a product from a plurality of regression models. In the conventional method, however, a user cannot intuitively confirm an improvement effect on each condition, and it is difficult to determine the validity of the change of the condition. In addition, in the conventional method, it is difficult to efficiently select an optimum condition from combinations of a plurality of regression models and a plurality of sample shot arrays.

### SUMMARY OF THE INVENTION

The present invention provides a technique advantageous in efficiently determining the optimum condition of a pattern forming apparatus.

The present invention in its one aspect provides an information processing apparatus including an obtaining unit configured to obtain a target value of a performance index of pattern formation, an estimation unit configured to estimate, for each of a plurality of regression models, an evaluation value of the performance index in a case where pattern formation is performed by correcting an array of a plurality of shot regions on a substrate, which is estimated by determining a plurality of sample shot regions from the plurality of shot regions based on the target value obtained by the obtaining unit and applying a regression model to the plurality of determined sample shot regions, and a controller configured to display the estimated evaluation value for each of the plurality of regression models on a display unit in a comparable form.

Further features of the present invention will become apparent from the following description of exemplary embodiments (with reference to the attached drawings).

### BRIEF DESCRIPTION OF THE DRAWINGS

FIG. 1 is a view showing the configuration of an exposure apparatus and an information processing apparatus;

FIG. 2 is a view showing the configuration of an alignment optical system;

FIG. 3 is a flowchart of exposure processing;

FIG. 4 is a view showing an example of sample shot regions;

FIG. 5 is a graph exemplifying the relationship between the number of sample points and a correction residual;

FIG. 6 is a view showing an example of a correction residual confirmation screen;

FIG. 7 is a view showing an example of a UI screen;

FIG. 8 is a view showing an example of the UI screen;

FIG. 9 is a view showing an example of the UI screen; and

FIG. 10 is a flowchart illustrating the procedure of optimization processing of an exposure recipe.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

The present disclosure is related to an information processing apparatus, an information processing method, a non-transitory computer-readable storage medium, a pattern forming apparatus, and an article manufacturing method. The pattern forming apparatus is an apparatus that forms a pattern on a substrate, and a lithography apparatus such as an exposure apparatus is a kind of pattern forming apparatus. The following embodiment will describe an example related to an exposure apparatus as an example of a lithography apparatus.

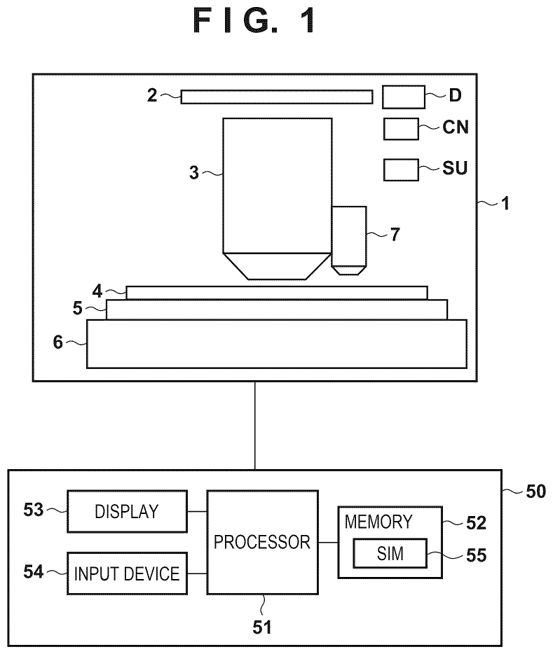

FIG. 1 is a view showing the configuration of an exposure apparatus 1 and a simulation apparatus 50 according to the embodiment. The exposure apparatus 1 is a kind of lithography apparatus used in the manufacturing step of a device such as a semiconductor element. In this embodiment, the exposure apparatus 1 projects the pattern of an original 2 (a reticle or a mask) onto a substrate 4 via a projection optical system 3, and exposes the substrate 4.

As shown in FIG. 1, the exposure apparatus 1 includes the projection optical system 3 that projects (reduction-projects) a pattern formed on the original 2, and a chuck 5 that holds the substrate 4 on which a base pattern or an alignment mark has been formed by a preprocess. The exposure apparatus 1 also includes a substrate stage 6 that holds the chuck 5 and positions the substrate 4 at a predetermined position, an alignment optical system 7 that measures the position of an alignment mark provided on the substrate 4, a controller CN, a storage unit SU, and a display unit D.

The controller CN is formed by, for example, a computer (information processing apparatus) including a CPU and a memory, and generally controls the units of the exposure apparatus 1 in accordance with a program stored in the storage unit SU or the like. In this embodiment, in addition to controlling exposure processing of exposing the substrate 4 via the original 2, the controller CN can function as a processor configured to obtain an array (a shot array) of a plurality of shot regions on the substrate (a plurality of regions on the substrate). On the display unit D, a user interface screen (UI screen) showing the setting, state, and the like of exposure processing is displayed. The controller CN can function as a display controller configured to control display of the UI screen.

The storage unit SU stores a program and various kinds of information (data) necessary to execute exposure processing of exposing the substrate 4 by controlling the units of the exposure apparatus 1. The storage unit SU also stores a program and various kinds of information (data) necessary for the controller CN to obtain the arrangement (the sample shot array) of the sample shot regions. Note that the controller CN, the storage unit SU, and the display unit D may be formed as external devices of the exposure apparatus 1. For example, an information processing apparatus including the controller CN, the storage unit SU, and the display unit D may be formed as a server apparatus configured to manage the exposure apparatus 1. An input device (a mouse, a keyboard, or the like) (not shown) operated by the user is also connected to the controller CN. Note that the storage unit SU may be a semiconductor memory, a disk such as a hard disk, or a memory in another form. A program for obtaining the arrangement of the sample shot regions may be stored in a computer-readable memory medium or may be provided to an information processing apparatus via a communication facility such as an electric communication network.

The simulation apparatus 50 (information processing apparatus) can be formed by, for example, installing a simulation program 55 in a general-purpose or dedicated computer. Alternatively, the simulation apparatus 50 may be formed by a Programmable Logic Device (PLD) such as a Field Programmable Gate Array (FPGA), or an Application Specific Integrated Circuit (ASIC). In an example, the simulation apparatus 50 can be formed by preparing a computer including a processor 51, a memory 52, a display 53 (display unit), and an input device 54, and storing the simulation program 55 in the memory 52. The memory 52 may be a semiconductor memory, a disk such as a hard disk, or a memory in another form. The input device 54 can include a mouse and a keyboard. The simulation program 55 can be stored in a non-transitory computer-readable memory medium or may be provided to the simulation apparatus 50 via a communication facility such as an electric communication network.

In the example shown in FIG. 1, the simulation apparatus 50 is formed as an external device of the exposure apparatus 1. Instead of this, the function of the simulation apparatus 50 may be implemented in the exposure apparatus 1. In this case, in the exposure apparatus 1, an information processing apparatus including the controller CN, the storage unit SU, and the display unit D can be formed as a simulation apparatus.

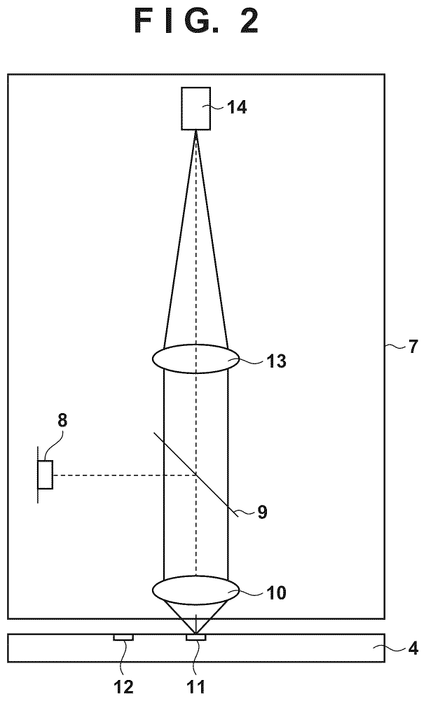

FIG. 2 is a schematic view showing the arrangement of the alignment optical system 7. The alignment optical system 7 has a function of optically detecting a mark assigned to each shot region on the substrate 4 and obtaining position measurement data, and, in this embodiment, includes a light source 8, a beam splitter 9, lenses 10 and 13, and a sensor 14.

Light from the light source 8 is reflected by the beam splitter 9 and illuminates, via the lens 10, an alignment mark 11 or 12 provided on the substrate 4. The light diffracted by the alignment mark 11 or 12 is received by the sensor 14 via the lens 10, the beam splitter 9, and the lens 13.

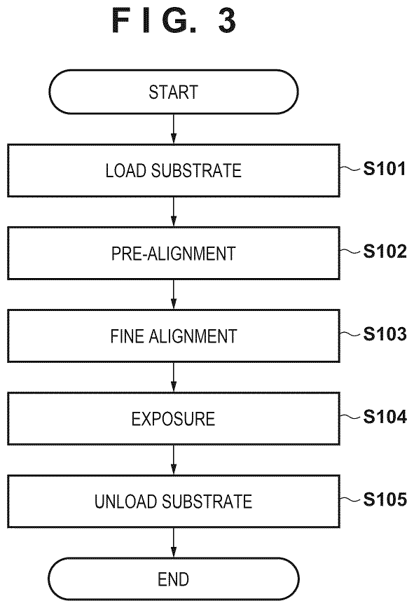

Exposure processing by the exposure apparatus 1 will be described with reference to FIG. 3. The outline of steps until the substrate 4 is aligned and exposed will be described here. In step S101, the substrate 4 is loaded into the exposure apparatus 1. In step S102, the controller CN executes pre-alignment. More specifically, the controller CN detects the alignment mark 11 for pre-alignment provided on the substrate 4 using the alignment optical system 7, thereby roughly obtaining the position of the substrate 4. At this time, detection of the alignment mark 11 is performed for a plurality of shot regions on the substrate 4, and the shift and the first-order linear component (magnification or rotation) of the entire substrate 4 are obtained.

In step S103, the controller CN executes fine alignment. More specifically, first, based on the result of pre-alignment, the controller CN drives the substrate stage 6 to a position where the alignment mark 12 for fine alignment provided on the substrate 4 can be detected by the alignment optical system 7. Then, the controller CN detects, using the alignment optical system 7, the alignment mark 12 provided in each of the plurality of shot regions on the substrate 4, thereby precisely obtaining the shift and the first-order linear component (magnification or rotation) of the entire substrate 4. At this time, the controller CN can also precisely obtain the high-order deformation component of the substrate 4 by obtaining the positions of a number of shot regions. This makes it possible to obtain the precise position of each shot region on the substrate 4, that is, the shot array.

In step S104, the controller CN exposes the substrate 4. More specifically, after the fine alignment is executed, the controller CN transfers the pattern of the original 2 to each shot region on the substrate 4 via the projection optical system 3. In step S105, the substrate 4 is unloaded from the exposure apparatus 1.

In this embodiment, if the substrate 4 is distorted, the high-order deformation component is corrected in the fine alignment of step S103. Note that correction by the exposure apparatus 1 can be implemented by, for example, driving the substrate stage 6, driving an original stage (not shown) that holds the original 2, and driving the optical element of the projection optical system 3. For example, as a regression model used to estimate the shot array, a fifth-order polynomial model can be used. However, the regression model is not limited to this. As the regression model, an arbitrary order model can be used. A model (a triangle function model or a logarithmic model) other than a polynomial model may be used. In this embodiment, simulation is performed for a plurality of regression models using the simulation apparatus 50, and the user can confirm the result to determine an appropriate regression model.

If the deformation of the substrate is expressed by a fifth-order polynomial model, the position deviations (ShiftX, ShiftY) of each shot region are represented by equations (1) below. Note that a position deviation of each shot region may be understood as a correction value used to correct the position deviation.

$$\begin{matrix}ShiftX = {k}_{1} + {k}_{3} x + {k}_{5} y \\ + {k}_{7} {x}^{2} + {k}_{9} xy + {k}_{11} {y}^{2} \\ + {k}_{13} {x}^{3} + {k}_{15} {x}^{2} y + {k}_{17} {xy}^{2} + {k}_{19} {y}^{3} \\ + {k}_{21} {x}^{4} + {k}_{23} {x}^{3} y + {k}_{25} {x}^{2} {y}^{2} + {k}_{27} {xy}^{3} + {k}_{29} {y}^{4} \\ + {k}_{31} {x}^{5} + {k}_{33} {x}^{4} y + {k}_{35} {x}^{3} {y}^{2} + {k}_{37} {x}^{2} {y}^{3} + {k}_{39} {xy}^{4} + {k}_{41} {y}^{5}\end{matrix} \qquad ( 1 )$$

$$\begin{matrix}ShiftY = {k}_{2} + {k}_{4} y + {k}_{6} x \\ + {k}_{8} {y}^{2} + {k}_{10} xy + {k}_{12} {x}^{2} \\ + {k}_{14} {y}^{3} + {k}_{16} {xy}^{2} + {k}_{18} {x}^{2} y + {k}_{20} {x}^{3} \\ + {k}_{22} {y}^{4} + {k}_{24} {xy}^{3} + {k}_{26} {x}^{2} {y}^{2} + {k}_{28} {x}^{3} y + {k}_{30} {x}^{4} \\ + {k}_{32} {y}^{5} + {k}_{34} {xy}^{4} + {k}_{36} {x}^{2} {y}^{3} + {k}_{38} {x}^{3} {y}^{2} + {k}_{40} {x}^{4} y + {k}_{42} {x}^{5}\end{matrix}$$

where x and y represent the positions of a shot region on the substrate 4. Coefficients k₁ to k₄₂ in equations (1) are determined based on the actual position measurement data of each shot region on the substrate 4. Then, the position deviation (correction value) of each shot region is obtained based on equations (1) in which the coefficients are determined.

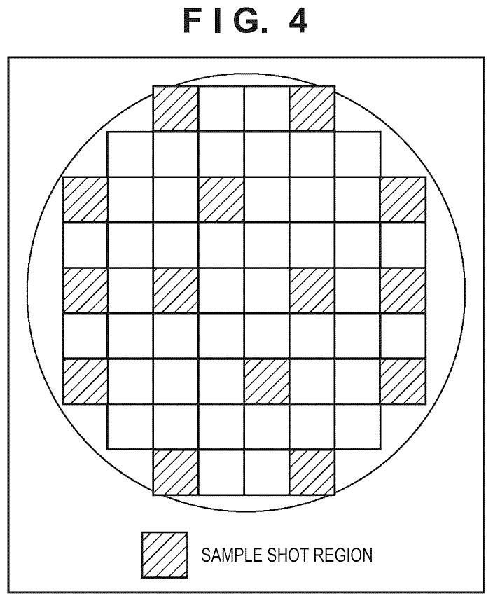

In the global alignment method, alignment measurement is executed in sample shot regions which are some of the plurality of shot regions on the substrate. FIG. 4 shows an example of the sample shot regions. Referring to FIG. 4, as an example, 14 sample shot regions are set on the substrate. In the global alignment method, the alignment mark 12 arranged in each of these sample shot regions is detected using the alignment optical system 7.

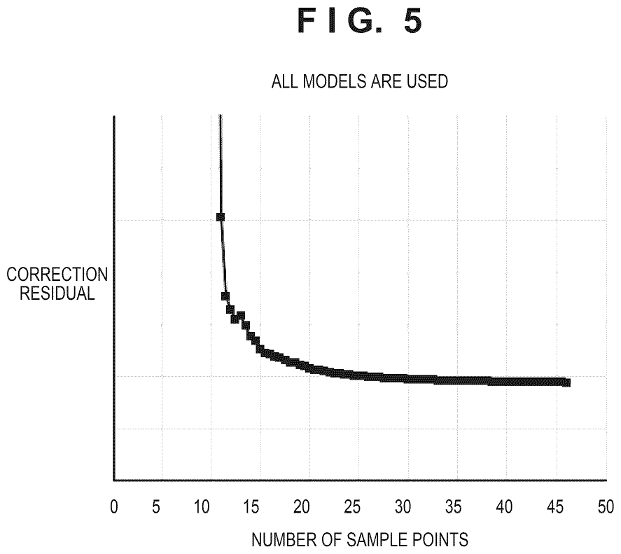

FIG. 5 is a graph showing an example of the relationship between the number of sample shot regions (the number of sample points) and a correction residual as an index of correction accuracy in a given device. The correction residual indicates an array error that cannot completely be corrected when correcting the array of the plurality of shot regions on the substrate using the plurality of determined sample shot regions. From the viewpoint of correction accuracy (measurement accuracy), the number of sample shot regions as actual measurement targets is desirably large. However, as the number of sample shot regions is larger, it is more disadvantageous in terms of measurement throughput. The number of sample shot regions is appropriately determined based on the tradeoff relationship between the correction accuracy and the throughput.

The optimal resolution of the number and arrangement (to be referred to as a “sample shot array” hereinafter) of sample shot regions changes depending on the processing step of a substrate and the characteristic of a device. Therefore, the optimum sample shot array changes depending on the alignment accuracy and productivity (throughput) required for each device.

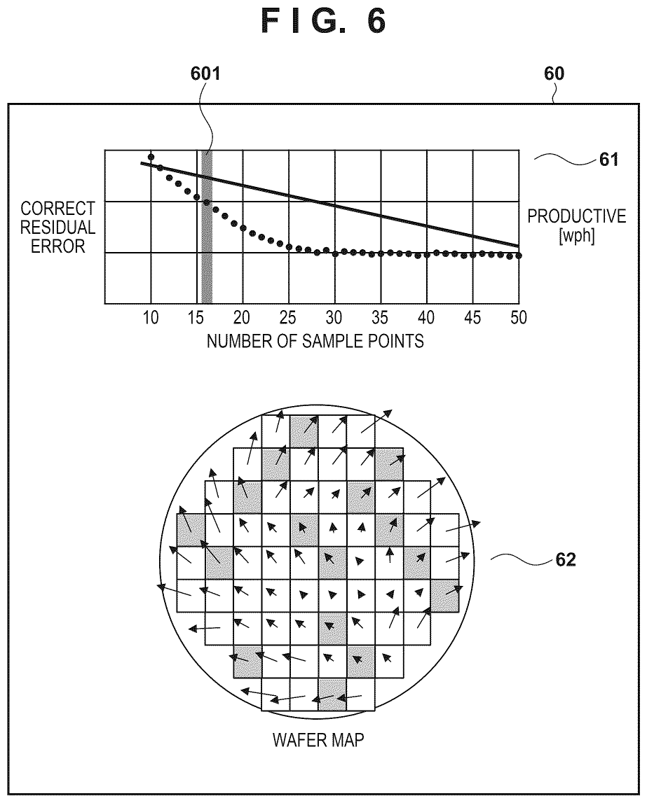

FIG. 6 is a view showing an example of a correction residual confirmation screen 60 displayed on the display 53 of the simulation apparatus 50 with respect to determination of the sample shot array. The confirmation screen 60 can include a graph display screen 61 showing the relationship between the number of sample points and each of the correction residual and productivity, and a wafer map display screen 62 showing the result of the arrangement of the sample shot regions on the substrate.

On the graph display screen 61, a graph showing transition of the correction residual (first ordinate) with respect to the number of sample points (abscissa) and a graph showing transition of productivity (second ordinate) with respect to the number of sample points are displayed. In this example, the productivity (throughput) is expressed by the number of substrates processed per unit time (wph). With reference to the graphs displayed on the graph display screen 61, the user can search for the number of sample points with which it is possible to make a compromise with respect to the correction residual (accuracy) and the productivity. In an example, the processor 51 determines a recommended value (the initial number of sample points) of the number of sample points based on the relationship between the number of sample points and each of the correction residual and productivity. After that, the processor 51 provisionally determines the arrangement of the sample shot regions by the initial number of sample points in accordance with a predetermined selection algorithm. As the selection algorithm, a known algorithm can be used. The selection algorithm is, for example, an algorithm of making a selection under a predetermined constraint such as the constraint that the set number of sample shot regions are equally arranged (without localization) symmetrically with respect to the center of the substrate as much as possible or the constraint that the set number of sample shot regions are arranged on the outer periphery of the substrate as many as possible. A further constraint that the shot region on the outermost periphery of the substrate is excluded from selection targets may be placed.

After that, the processor 51 determines the sample shot array by a method using a regression model (correction model) with respect to the provisionally determined arrangement of the sample shot regions. The processor 51 controls the confirmation screen 60 so that the determined sample shot array is displayed on the wafer map display screen 62.

The number of sample points can be changed by a user operation. For example, when a mouse pointer overlaps the graph of the graph display screen 61, a partial region 101 including the position of the mouse pointer is displayed in a specific color by the rollover effect. If the mouse is clicked in this state, the number of sample points corresponding to the partial region 101 is set. In this way, the user can designate the number of sample shot regions. That is, in this embodiment, the graph display screen 61 is a designation screen used by the user to designate the number of sample shot regions.

The wafer map display screen 62 is a display screen that displays information of the position of each of the plurality of sample shot regions on the substrate. When the number of sample points is designated or changed, the processor 51 redetermines the arrangement of the shot regions. After that, the processor 51 updates the display so that the redetermined sample shot array is displayed on the wafer map display screen 62. FIG. 6 shows a result in a case where 16 sample points are set. In this way, with respect to the number of sample points arbitrarily designated by the user, the predicted correction accuracy and productivity and an optimum sample shot array are displayed. This allows the user to readily confirm the effect of adjustment of the parameter for determining the sample shot regions.

The correction residual information for each shot region is displayed on the wafer map display screen 62. For example, as shown in FIG. 6, on the wafer map display screen 62, the correction residual of each shot region can be displayed by an arrow representing the direction and magnitude on the X-Y plane (substrate surface). This allows the user to readily confirm the correction effect for each shot region. The display by the arrow representing the direction and magnitude on the X-Y plane will also be referred to as “vector display” hereinafter. The display of the direction and magnitude of the correction residual of each shot region is not limited to the display form shown in FIG. 6. For example, the magnitude in each of the X and Y directions of the correction residual of each shot region may be displayed by an arrow or a numerical value. Note that FIG. 6 shows an example of one confirmation screen for one specific regression model. A plurality of confirmation screens can be provided for a plurality of regression models.

In the above-described example shown in FIG. 6, the user can confirm a correction result on the calculated condition. However, it is difficult to confirm an improvement effect on the conventional condition or another regression model.

An embodiment including display with which the user can visually confirm an improvement effect will be described below.

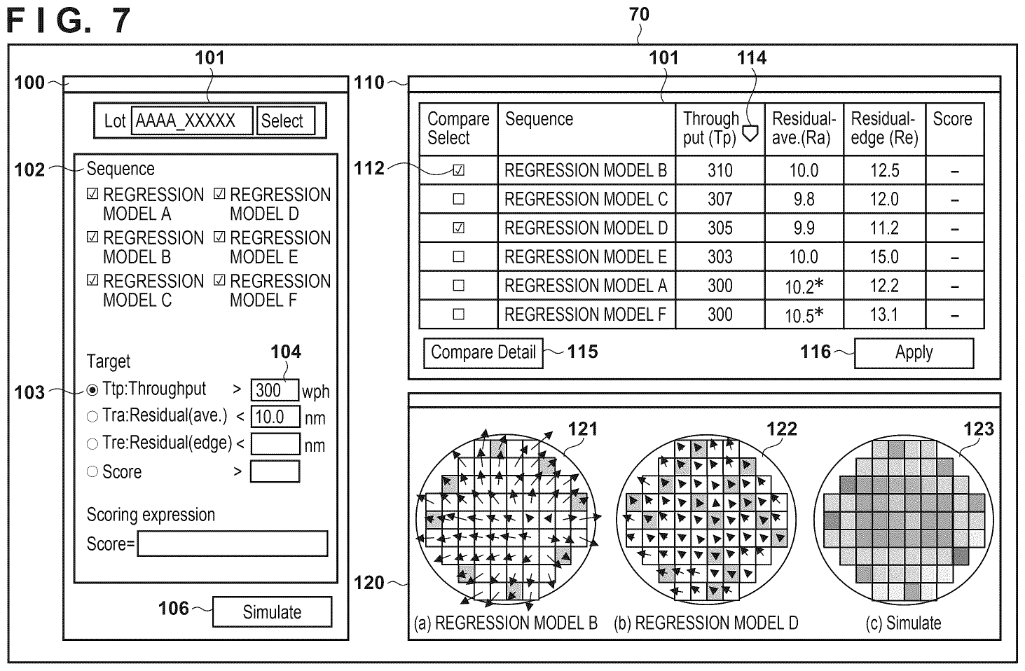

FIG. 7 is a view showing an example of a user interface (UI) screen 70 displayed on the display 53 according to this embodiment. The UI screen 70 can include a correction setting screen 100, a result display screen 110, and a detail comparison screen 120.

The correction setting screen 100 is a screen for setting and confirming a correction condition. The correction setting screen 100 includes a lot selection portion 101. In the lot selection portion 101, the user can select a lot as a correction target.

The correction setting screen 100 includes a regression model selection portion 102. In the regression model selection portion 102, the user can select one or more regression models as calculation targets from a plurality of regression models A to F prepared in advance. The plurality of regression models can include, for example, as regression models used to estimate a shot array, a third-order polynomial model, a fourth-order polynomial model, a fifth-order polynomial model, a Zernike polynomial model, and a Gaussian function model.

The correction setting screen 100 further includes a target value setting portion 104 for setting a target value for each performance index of pattern formation. The user can input a target value to the target value setting portion 104 with respect to one or more of a plurality of performance indices (for example, throughput, correction residual (average), correction residual (edge weighted average), and the like). In this way, the correction setting screen 100 (target value setting portion 104) functions as an obtaining unit configured to obtain the target value of the performance index of pattern formation.

The correction setting screen 100 further includes a performance index selection portion 103 for selecting a priority performance index among the plurality of performance indices. In the example shown in FIG. 7, the performance index selection portion 103 is implemented by a radio button provided for each performance index, and a state in which “throughput” is selected is shown. In this way, the correction setting screen 100 (performance index selection portion 103) as an obtaining unit can further obtain priority designation for one of the plurality of performance indices.

A simulate button 106 is prepared in the lower portion of the correction setting screen 100. When the user clicks the simulate button 106, the processor 51 determines a plurality of sample shot regions from the plurality of shot regions on the substrate for each of the plurality of regression models selected in the regression model selection portion 102. More specifically, for each of the plurality of regression models selected as calculation targets in the regression model selection portion 102, the processor 51 determines a plurality of sample shot regions based on the target value input to the target value setting portion 104. After that, the processor 51 estimates an array error of the plurality of shot regions based on the plurality of determined sample shot regions. Then, the processor 51 estimates the evaluation value of each performance index in a case where pattern formation is performed by correcting the array of the plurality of shot regions obtained by the estimation (by simulation). After that, the processor 51 displays the calculation result (the evaluation value for each regression model) on the result display screen 110 on the display 53. On the result display screen 110, the evaluation value of each performance index obtained by the estimation for each regression model is displayed. At this time, with respect to the regression model that cannot satisfy the target performance, no evaluation value is displayed or the evaluation value may be displayed with an annotation (for example, a mark “*”).

On the result display screen 110, the evaluation value of each performance index obtained by the estimation for each regression model is displayed in a comparable form. For example, as shown in FIG. 7, a list of the plurality of estimated evaluation values for the regression models is displayed on the result display screen 110. Among the plurality of performance indices on the result display screen 110, the performance index (that is, the performance index with priority designation) selected in the performance index selection portion 103 is added with a priority mark 114. In the example shown in FIG. 7, since “throughput” is selected in the performance index selection portion 103, “throughput” on the result display screen 110 is added with the priority mark 114. The processor 51 sorts the list in preferable order (ascending order or descending order) of the evaluation value of the performance index with priority designation, and displays the list on the display 53. For example, in a case where the performance index with priority designation is throughput representing the number of substrates processed per unit time, the list is sorted in descending order of the evaluation value.

The result display screen 110 includes a comparison selection portion 112. In the comparison selection portion 112, the user can select two regression models as comparison targets (detail comparison targets). In this way, in the comparison selection portion 112, it is possible to further accept designation of two regression models as comparison targets from the list.

A detail comparison button 115 is prepared in the lower portion of the result display screen 110. When the user clicks the detail comparison button 115, information of the positions of the plurality of determined sample shot regions on the substrate and information of the correction residuals of the plurality of shot regions are further displayed on the display 53 for each of the two regression models. For example, the processor 51 displays, on the detail comparison screen 120, wafer maps 121 and 122 by the two regression models selected in the comparison selection portion 112. On each of the wafer maps 121 and 122, the sample shot array obtained by calculation is displayed and information of the correction residual of each shot region is also displayed by, for example, vector display.

The processor 51 can also display, on the display 53, information of a difference in correction residual between the two regression models in each of the plurality of shot regions. For example, the processor 51 further displays, on the detail comparison screen 120, a difference map 123 representing a difference (improvement effect) between the correction residual of each shot region indicated on the wafer map 121 and the correction residual of each shot region indicated on the wafer map 122. Referring to FIG. 7, as the difference map 123, the magnitude of the difference between the correction residual of each shot region indicated on the wafer map 121 and the correction residual of each shot region indicated on the wafer map 122 is displayed by colors, more specifically, color shades (gradations). However, as the difference map 123, the magnitude of the difference between the correction residual of each shot region indicated on the wafer map 121 and the correction residual of each shot region indicated on the wafer map 122 may be displayed using color types (hues) instead of the color shades. For example, if the number of sample points is changed, a shot region in which the correction residual is improved is displayed in blue, and a shot region in which the correction residual is not improved is displayed in red.

As described above, the user confirms the wafer maps 121 and 122 and the difference map 123 displayed on the detail comparison screen 120. After this confirmation, the user finally selects one regression model in the comparison selection portion 112, and clicks a confirmation button 116, thereby confirming the regression model to be applied.

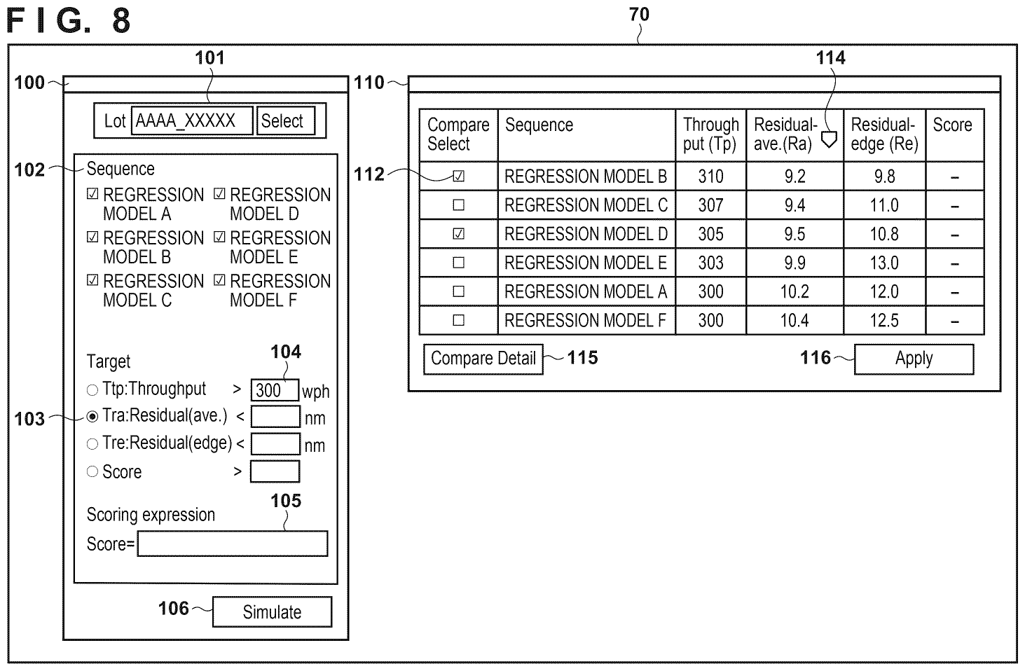

An example of preferentially displaying a regression model whose correction residual is satisfactory will be described next with reference to FIG. 8. Referring to FIG. 8, “correction residual (average)” is selected in the performance index selection portion 103. When the user clicks the simulate button 106 in this state, the processor 51 performs, for each of the regression models selected as calculation targets in the regression model selection portion 102, determination of a sample shot array and calculation of each evaluation value. After that, the processor 51 displays the calculation results (the evaluation values for the regression models) on the result display screen 110. On the result display screen 110, the evaluation values respectively calculated to satisfy the set target performances are displayed. Among the plurality of target performances on the result display screen 110, the target performance selected in the performance index selection portion 103 is added with the priority mark 114. In the example shown in FIG. 8, since “correction residual (average)” is selected in the performance index selection portion 103, “correction residual (average)” on the result display screen 110 is added with the priority mark 114. Therefore, the processor 51 sorts the list in ascending order of the correction residual (average), and displays it on the result display screen 110. This makes it easy to select the regression model by giving priority to the correction residual.

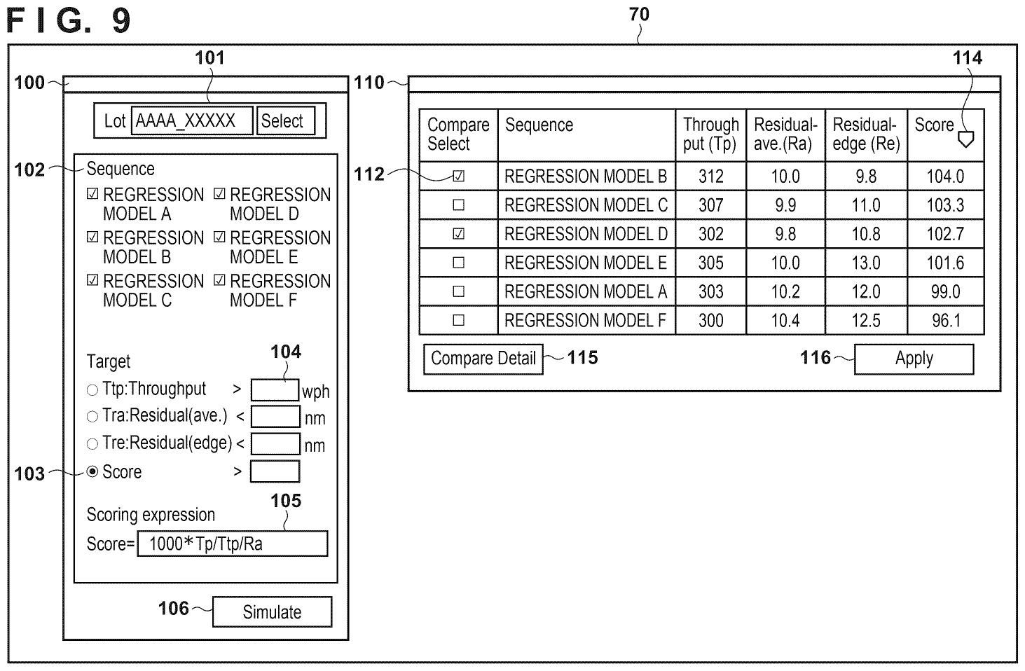

An example of preferentially displaying a regression model whose total evaluation score for the plurality of performances is satisfactory will be described next with reference to FIG. 9. Referring to FIG. 9, “score” indicating the total evaluation score using a plurality of performance indices (which include, for example, the throughput and the correction residual) is selected in the performance index selection portion 103. In this case, the user can designate, in an evaluation expression setting portion 105, an evaluation expression for obtaining the score. When the user clicks the simulate button 106 in this state, the processor 51 performs, for each of the regression models selected as calculation targets in the regression model selection portion 102, determination of a sample shot array and calculation of each evaluation value. After that, the processor 51 displays the calculation results (the evaluation values for the regression models) on the result display screen 110. On the result display screen 110, the evaluation values respectively calculated to satisfy the set target performances are displayed. Among the plurality of performance indices on the result display screen 110, the performance index selected in the performance index selection portion 103 is added with the priority mark 114. In the example shown in FIG. 9, since “score” is selected in the performance index selection portion 103, “score” on the result display screen 110 is added with the priority mark 114. Therefore, the processor 51 sorts the list in descending order of the evaluation value of the score, and displays it on the result display screen 110.

In the example shown in FIG. 7, an example of displaying the difference map 123 with respect to the correction residual is shown. The correction residual used here can be a correction residual calculated based on the statistic value (for example, the average value) of position measurement data obtained from a plurality of substrates for each of a plurality of different conditions (for example, a plurality of different sample shot arrays). Instead of this, the correction residual of each substrate under the same condition, which is predicted from the position measurement data obtained from each of the plurality of substrates, and the difference between the correction residuals can be displayed as a difference map.

In the above-described example, an example for evaluation of the correction residual (improvement effect) with respect to a sample shot array in fine alignment has been explained, but the present invention is not limited to this. For example, the present invention can also be applied to evaluation of the position deviation (improvement effect) of each shot region in the height direction with respect to a focus control parameter for controlling the position of a substrate in the height direction when exposing the substrate. More specifically, the processor 51 predicts the position deviation of each shot region in the height direction before and after the change of the focus control parameter. After that, the processor 51 generates a map representing the position deviation of each shot region in the height direction corresponding to each of the focus control parameters before and after the change, and displays the map. The processor 51 calculates, for each shot region, the difference between the position deviations in the height direction predicted for the focus control parameters before and after the change, generates a difference map, and displays it.

This allows the user to readily confirm, for each of the plurality of shot regions on the substrate, the change (improvement effect) of the position deviation in the height direction for each focus control parameter (condition), thereby determining the validity of the focus control parameter.

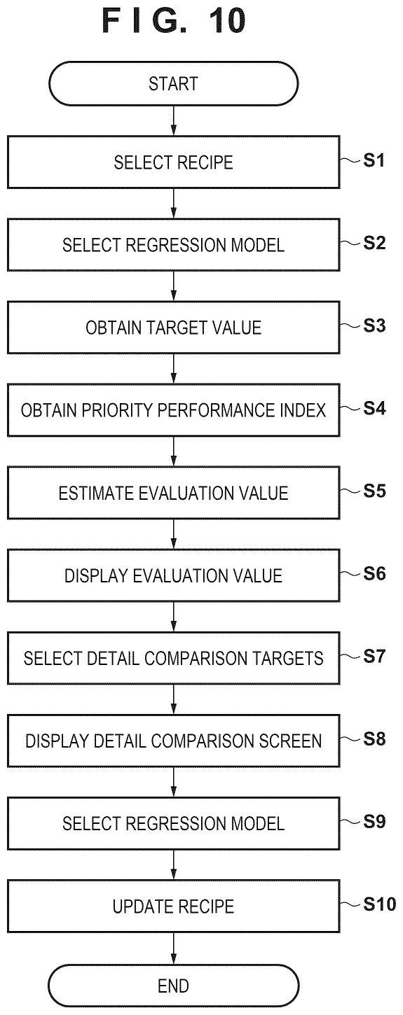

A practical example of optimization processing of an exposure recipe will be described with reference to FIG. 10. FIG. 10 is a flowchart illustrating the procedure (simulation method) of the optimization processing of the exposure recipe.

In step S1, the processor 51 selects an exposure recipe (to be simply referred to as a “recipe” hereinafter) to be optimized. The recipe is a set of various kinds of control parameters for defining an exposure condition, the processing procedure of a substrate, and the like. The processor 51 executes exposure processing in accordance with the recipe.

In step S2, the processor 51 selects a regression model as a comparison target. This can be performed when the user selects one or more regression models in the regression model selection portion 102 of the UI screen 70 shown in FIG. 7.

In step S3, the processor 51 obtains a target value. This can be performed when the user obtains the target value input to the target value setting portion 104.

In step S4, the processor 51 designates a priority performance index. This is performed by user selection in the performance index selection portion 103

When the user clicks the simulate button 106, the processor 51 performs, in step S5, calculation (estimation) of each evaluation value for each of the regression models selected in the regression model selection portion 102, and determines a sample shot array.

In step S6, the processor 51 displays the calculation results (the evaluation values for the regression models) on the result display screen 110. The processor 51 sorts the list in ascending order or descending order of the evaluation value of the performance index designated in step S4, and displays the list on the result display screen 110.

In step S7, the user can select two regression models as detail comparison targets in the comparison selection portion 112. After that, when the user clicks the detail comparison button 115, the processor 51 displays, on the detail comparison screen 120, the wafer maps 121 and 122 and the difference map 123 by the two regression models selected in the comparison selection portion 112. In step S8, the user can perform detail comparison of the two regression models using the wafer maps 121 and 122 and the difference map 123 displayed on the detail comparison screen 120.

In step S9, the processor 51 selects the regression model to be applied. This is performed when the user finally selects one regression model in the comparison selection portion 112 and clicks the confirmation button 116.

In step S10, based on a simulation result obtained when the regression model selected in step S9 is applied, the processor 51 updates the recipe selected in step S1.

According to the above-described processing procedure, it is possible to efficiently determine the optimum condition of the exposure apparatus.

### Embodiment of Article Manufacturing Method

An article manufacturing method according to the embodiment of the present invention is suitable for manufacturing an article, for example, a microdevice such as a semiconductor device or an element having a fine structure. The article manufacturing method according to the embodiment includes a step of transferring, using the above-described lithography apparatus (an exposure apparatus, an imprint apparatus, a drawing apparatus, or the like), the pattern of an original to a substrate, and a step of processing the substrate to which the pattern has been transferred in the above step. In addition, the manufacturing method includes other well-known steps (oxidation, film formation, deposition, doping, planarization, etching, resist removal, dicing, bonding, packaging, and the like). The article manufacturing method according to this embodiment is more advantageous than the conventional methods in at least one of the performance, quality, productivity, and production cost of the article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-066824, filed Apr. 17, 2024, which is hereby incorporated by reference herein in its entirety.

What is claimed is:

1. An information processing apparatus comprising:
an obtaining unit configured to obtain a target value of a performance index of pattern formation;
an estimation unit configured to estimate, for each of a plurality of regression models, an evaluation value of the performance index in a case where pattern formation is performed by correcting an array of a plurality of shot regions on a substrate, which is estimated by determining a plurality of sample shot regions from the plurality of shot regions based on the target value obtained by the obtaining unit and applying a regression model to the plurality of determined sample shot regions; and
a controller configured to display the estimated evaluation value for each of the plurality of regression models on a display unit in a comparable form.

2. The apparatus according to claim 1, wherein
the obtaining unit obtains a target value of each of a plurality of performance indices,
the estimation unit estimates an evaluation value of each of the plurality of performance indices, and the controller displays, for each of the plurality of regression models, the plurality of estimated evaluation values on the display unit.

3. The apparatus according to claim 2, wherein the plurality of performance indices include throughput and a correction residual obtained by correcting the array of the plurality of shot regions.

4. The apparatus according to claim 3, wherein the plurality of performance indices further include a total evaluation score obtained using the throughput and the correction residual.

5. The apparatus according to claim 4, wherein
the obtaining unit further obtains designation of an evaluation expression for obtaining the total evaluation score, and
the controller obtains the total evaluation score using the evaluation expression designated by the obtaining unit and displays the total evaluation score on the display unit.

6. The apparatus according to claim 3, wherein the controller displays, for each of the plurality of regression models, a list of the plurality of estimated evaluation values on the display unit.

7. The apparatus according to claim 6, wherein
the obtaining unit further obtains priority designation for one of the plurality of performance indices, and
the controller sorts the list in one of ascending order and descending order of the evaluation value of the performance index with the priority designation and displays the list on the display unit.

8. The apparatus according to claim 6, wherein
the obtaining unit further obtains designation of two regression models as comparison targets from the list displayed on the display unit, and
the controller further displays, on the display unit, for each of the two regression models, information of positions of the plurality of decided sample shot regions on the substrate and information of the correction residuals of the plurality of shot regions.

9. The apparatus according to claim 8, wherein the controller further displays, on the display unit, information of a difference in the correction residual between the two regression models in each of the plurality of shot regions.

10. An information processing method comprising:
obtaining a target value of a performance index of pattern formation;
estimating, for each of a plurality of regression models, an evaluation value of the performance index in a case where pattern formation is performed by correcting an array of a plurality of shot regions on a substrate, which is estimated by determining a plurality of sample shot regions from the plurality of shot regions based on the target value obtained in the obtaining and applying a regression model to the plurality of determined sample shot regions; and
displaying the estimated evaluation value for each of the plurality of regression models on a display unit in a comparable form.

11. A non-transitory computer-readable storage medium storing a program for causing a computer to function as:
an obtaining unit configured to obtain a target value of a performance index of pattern formation;
an estimation unit configured to estimate, for each of a plurality of regression models, an evaluation value of the performance index in a case where pattern formation is performed by correcting an array of a plurality of shot regions on a substrate, which is estimated by determining a plurality of sample shot regions from the plurality of shot regions based on the target value obtained by the obtaining unit and applying a regression model to the plurality of determined sample shot regions; and
a controller configured to display the estimated evaluation value for each of the plurality of regression models on a display unit in a comparable form.

12. A pattern forming apparatus for forming a pattern on a substrate, comprising:
an obtaining unit configured to obtain a target value of a performance index of pattern formation;
an estimation unit configured to estimate, for each of a plurality of regression models, an evaluation value of the performance index in a case where pattern formation is performed by correcting an array of a plurality of shot regions on a substrate, which is estimated by determining a plurality of sample shot regions from the plurality of shot regions based on the target value obtained by the obtaining unit and applying a regression model to the plurality of determined sample shot regions; and
a controller configured to display the estimated evaluation value for each of the plurality of regression models on a display unit in a comparable form.

13. An article manufacturing method comprising:
forming a pattern on a substrate using a pattern forming apparatus defined in claim 12; and
processing the substrate on which the pattern has been formed,
wherein an article is manufactured from the processed substrate.
